(19) United States
(12) Patent Application Publication
(10) Pub. No.: US 2026/0179546 A1
(43) Pub. Date: Jun. 25, 2026

(54) DISPLAY SUBSTRATE AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN); Beijing BOE Technology Development Co., Ltd., Beijing (CN)

(72) Inventors: Tiaomei Zhang, Beijing (CN); Hongbo Ma, Beijing (CN); Jianpeng Wu, Beijing (CN); Zhiliang Jiang, Beijing (CN); Ming Hu, Beijing (CN); Haijun Qiu, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN); Beijing BOE Technology Development Co., Ltd., Beijing (CN)

(21) Appl. No.: 18/837,240

(22) PCT Filed: Sep. 20, 2023
(86) PCT No.: PCT/CN2023/120043

§ 371 Date: Aug. 9, 2024

(51) Int. Cl. G09G 3/3233; G09G 3/20; H10K 59/121; H10K 59/131

(52) U.S. Cl. CPC G09G 3/3233; H10K 59/1213; H10K 59/131; G09G 3/2074; G09G 2300/0426; G09G 2300/0819; G09G 2300/0842; G09G 2300/0861; G09G 2310/08; G09G 2320/04; G09G 2330/021

(57) ABSTRACT

The present disclosure provides a display substrate and a display device. The display substrate includes a base substrate, and a plurality of sub-pixels, a plurality of first scanning lines, a plurality of second scanning lines and a plurality of data lines arranged on the base substrate. Each sub-pixel includes a sub-pixel driving circuitry, and the sub-pixel driving circuitry includes a driving transistor, a capacitor structure, a compensation transistor and a data write-in transistor.

### TECHNICAL FIELD

The present disclosure relates to the field of display technology, in particular to a display substrate and a display device.

### BACKGROUND

As a self-luminous screen made of an organic material, an Active-Matrix Organic Light-Emitting Diode (AMOLED) display screen does not include any backlight plate which is used in a liquid crystal display screen. When a current passes through a light-emitting layer made of the organic material, a sub-pixel emits light. As compared with the liquid crystal display screen, the AMOLED display screen has such advantages as purer color and higher contrast, so it has a wide market prospect.

### SUMMARY

An object of the present disclosure is to provide a display substrate and a display device, so as to solve problems in the related art.

In order to achieve the above-mentioned object, the present disclosure provides the following technical solutions.

In one aspect, the present disclosure provides in some embodiments a display substrate, including a base substrate, and a plurality of sub-pixels, a plurality of first scanning lines, a plurality of second scanning lines and a plurality of data lines arranged on the base substrate. Each sub-pixel includes a sub-pixel driving circuitry, and the sub-pixel driving circuitry includes a driving transistor, a capacitor structure, a compensation transistor and a data write-in transistor. A gate electrode of the compensation transistor is coupled to a corresponding first scanning line, a first electrode of the compensation transistor is coupled to a second electrode of the driving transistor, and a second electrode of the compensation transistor is coupled to a gate electrode of the driving transistor. A gate electrode of the data write-in transistor is coupled to a corresponding second scanning line, a first electrode of the data write-in transistor is coupled to a corresponding data line, a second electrode of the data write-in transistor is coupled to a first end of the capacitor structure, and a second end of the capacitor structure is coupled to the gate electrode of the driving transistor.

In a possible embodiment of the present disclosure, the driving transistor includes a top gate electrode, a bottom gate electrode and a driving active layer, at least a part of the bottom gate electrode is arranged between the top gate electrode and the base substrate, at least a part of the driving active layer is arranged between the top gate electrode and the bottom gate electrode, and the top gate electrode is coupled to the bottom gate electrode through a first conductive connection member.

In a possible embodiment of the present disclosure, the capacitor structure includes a first plate and a second plate, the first plate is arranged between the second plate and the base substrate, the first plate is coupled to the bottom gate electrode to form an integral piece, and the second plate is coupled to the second electrode of the data write-in transistor to form an integral piece.

In a possible embodiment of the present disclosure, the capacitor structure further includes a third plate, the second plate is arranged between the first plate and the third plate, and the third plate is coupled to the first conductive connection member.

In a possible embodiment of the present disclosure, the first scanning line includes a plurality of first scanning members and a plurality of second scanning members, the first scanning members and the second scanning members are arranged alternately along a first direction, and each first scanning member is coupled to the adjacent second scanning member. An orthogonal projection of the first scanning member onto the base substrate and an orthogonal projection of the capacitor structure onto the base substrate are arranged along the first direction, and the second scanning member extends along an extension direction of a part of a boundary of the capacitor structure.

In a possible embodiment of the present disclosure, the data write-in transistor includes a double-gate transistor.

In a possible embodiment of the present disclosure, the data write-in transistor includes a data write-in active layer, the gate electrode of the data write-in transistor has a U-shaped structure, and an orthogonal projection of the gate electrode of the data write-in transistor onto the base substrate overlaps with an orthogonal projection of the data write-in active layer onto the base substrate at two overlapping regions.

In a possible embodiment of the present disclosure, the display substrate further includes a first initialization signal layer and first resetting signal lines, the sub-pixel driving circuitry further includes a first resetting transistor, a gate electrode of the first resetting transistor is coupled to a corresponding first resetting signal line, a first electrode of the first resetting transistor is coupled to the first initialization signal layer, a second electrode of the first resetting transistor is coupled to the gate electrode of the driving transistor, and at least one of the first resetting transistor or the compensation transistor includes an oxide transistor.

In a possible embodiment of the present disclosure, the first initialization signal layer includes a plurality of first initialization signal lines and a plurality of second initialization signal lines, each first initialization signal line includes at least a part extending in a first direction, each second initialization signal line includes at least a part extending in a second direction, the first direction intersects the second direction, and the first initialization signal line is coupled to the second initialization signal line.

In a possible embodiment of the present disclosure, the display substrate further includes a second initialization signal layer and second resetting signal lines. The sub-pixel driving circuitry further includes a second resetting transistor, a gate electrode of the second resetting transistor is coupled to a corresponding second resetting signal line, a first electrode of the second resetting transistor is coupled to the second initialization signal layer, and a second electrode of the second resetting transistor is coupled to an anode of a light-emitting element in the sub-pixel. The second initialization signal layer includes a plurality of third initialization signal lines and a plurality of fourth initialization signal lines, each third initialization signal line includes at least a part extending in the first direction, each fourth initialization signal line includes at least a part extending in the second direction, and the third initialization signal line is coupled to the fourth initialization signal line.

In a possible embodiment of the present disclosure, the display substrate further includes a cathode layer and at least one cathode compensation layer, at least a part of the cathode compensation layer is arranged between the cathode layer and the base substrate, and the cathode compensation layer includes a plurality of cathode compensation lines coupled to the cathode layer.

In a possible embodiment of the present disclosure, the display substrate includes a first cathode compensation layer and a second cathode compensation layer, at least a part of the first cathode compensation layer is arranged between the second cathode compensation layer and the base substrate, the first cathode compensation layer includes a plurality of first cathode compensation lines, each first cathode compensation line includes at least a part extending in the first direction, the second cathode compensation layer includes a plurality of second cathode compensation lines, each second cathode compensation line includes at least a part extending in the second direction, and the first cathode compensation line is coupled to the second cathode compensation line.

In a possible embodiment of the present disclosure, the second initialization signal lines, the fourth initialization signal lines and the second cathode compensation lines are arranged alternately in the first direction.

In a possible embodiment of the present disclosure, the first resetting transistor includes a first resetting active layer, and the compensation transistor includes a compensation active layer. The display substrate further includes a plurality of power lines, each power line includes at least a part extending in the second direction, an orthogonal projection of the power line onto the base substrate at least partially overlaps with an orthogonal projection of the first resetting active layer onto the base substrate, and/or the orthogonal projection of the power line onto the base substrate at least partially overlaps with an orthogonal projection of the compensation active layer onto the base substrate.

In a possible embodiment of the present disclosure, the display substrate further includes a plurality of power compensation lines, each power compensation line includes at least a part extending in the first direction, the first direction intersects the second direction, and the power compensation line is coupled to the power line.

In a possible embodiment of the present disclosure, the data line is arranged between the power line and the second initialization signal line; and/or the data line is arranged between the power line and the fourth initialization signal line; and/or the data line is arranged between the power line and the second cathode compensation line.

In a possible embodiment of the present disclosure, the display substrate further includes a plurality of first light-emission control signal lines and a plurality of second light-emission control signal lines, and the sub-pixel driving circuitry further includes a power control transistor and a light-emission control transistor. A gate electrode of the power control transistor is coupled to a corresponding first light-emission control signal line, a first electrode of the power control transistor is coupled to a corresponding power line, and a second electrode of the power control transistor is coupled to a first electrode of the driving transistor. A gate electrode of the light-emission control transistor is coupled to a corresponding second light-emission control signal line, a first electrode of the light-emission control transistor is coupled to the second electrode of the driving transistor, and a second electrode of the light-emission control transistor is coupled to the anode of the light-emitting element in the sub-pixel.

In a possible embodiment of the present disclosure, the first initialization signal line, the first resetting signal line, the second scanning line, the first scanning line, the first light-emission control signal line, the power compensation line, the second light-emission control signal line, the second resetting signal line, the third initialization signal line and the first cathode compensation line are sequentially arranged in the second direction in a layout region of a same sub-pixel driving circuitry.

In a possible embodiment of the present disclosure, the display substrate includes a first source/drain metal layer, and the first initialization signal line, the first resetting signal line, the second scanning line, the first scanning line, the first light-emission control signal line, the power compensation line, the second light-emission control signal line, the second resetting signal line, the third initialization signal line and the first cathode compensation line are arranged at a same layer and made of a same material as the first source/drain metal layer.

In another aspect, the present disclosure provides in some embodiments a display device including the above-mentioned display substrate.

### BRIEF DESCRIPTION OF THE DRAWINGS

The following drawings are provided to facilitate the understanding of the present disclosure, and constitute a portion of the description. These drawings and the following embodiments are for illustrative purposes only, but shall not be construed as limiting the present disclosure. In these drawings,

FIG. 1 is a circuit diagram of a sub-pixel driving circuitry according to one embodiment of the present disclosure;

FIG. 2 is a sequence diagram of the sub-pixel driving circuitry according to one embodiment of the present disclosure;

FIG. 3 is a sectional view of a part of film layers of a display substrate according to one embodiment of the present disclosure;

FIG. 4 is a schematic view showing the arrangement of a light-shielding layer in the display substrate according to one embodiment of the present disclosure;

FIG. 5 is a schematic view showing the arrangement of a polysilicon active layer in the display substrate according to one embodiment of the present disclosure;

FIG. 6 is a schematic view showing the arrangement of a first gate metal layer in the display substrate according to one embodiment of the present disclosure;

FIG. 7 is a schematic view showing the arrangement of a second gate metal layer in the display substrate according to one embodiment of the present disclosure;

FIG. 8 is a schematic view showing the arrangement of an oxide active layer in the display substrate according to one embodiment of the present disclosure;

FIG. 9 is a schematic view showing the arrangement of a third gate metal layer in the display substrate according to one embodiment of the present disclosure;

FIG. 10 is a schematic view showing the arrangement of a part of via holes in an interlayer insulation layer in the display substrate according to one embodiment of the present disclosure;

FIG. 11 is another schematic view showing the arrangement of a part of via holes in the interlayer insulation layer in the display substrate according to one embodiment of the present disclosure;

FIG. 12 is a schematic view showing the arrangement of a first source/drain metal layer in the display substrate according to one embodiment of the present disclosure;

FIG. 13 is a schematic view showing the via holes formed in a first planarization layer in the display substrate according to one embodiment of the present disclosure;

FIG. 14 is a schematic view showing the arrangement of a second source/drain metal layer in the display substrate according to one embodiment of the present disclosure;

FIG. 15 is a schematic view showing the arrangement of the polysilicon active layer and the first gate metal layer in the display substrate according to one embodiment of the present disclosure;

FIG. 16 is a schematic view showing the addition of the light-shielding layer on the basis of FIG. 15;

FIG. 17 is a schematic view showing the addition of a second gate metal layer on the basis of FIG. 16;

FIG. 18 is a schematic view showing the arrangement of the oxide active layer, the second gate metal layer and a third gate metal layer in the display substrate according to one embodiment of the present disclosure;

FIG. 19 is a schematic view showing the addition of the interlayer insulation layer and the first source/drain metal layer on the basis of FIG. 16:

FIG. 20 is a schematic view showing the addition of the interlayer insulation layer and the first source/drain metal layer on the basis of FIG. 18;

FIG. 21 is a schematic view showing the addition of the oxide active layer, the second gate metal layer and the third gate metal layer on the basis of FIG. 15;

FIG. 22 is a schematic view showing the addition of the interlayer insulation layer and the first source/drain metal layer on the basis of FIG. 21;

FIG. 23 is a schematic view showing the addition of the first planarization layer and the second source/drain metal layer on the basis of FIG. 22; and

FIG. 24 is a schematic view showing the arrangement of the first source/drain metal layer and the second source/drain metal layer in the display substrate according to one embodiment of the present disclosure.

### DETAILED DESCRIPTION

The present disclosure will be described hereinafter in conjunction with the drawings and embodiments.

In active matrix display, a current flowing through each OLED element is controlled, so as to control a single sub-pixel. Hence, after an image is displayed by an AMOLED display screen, the sub-pixels need to be initialized, and then a data signal corresponding to a next image is rewritten to control the current, so as to display the next image. In this process, the current flowing through a driving transistor and the OLED element, and thereby brightness of the sub-pixel, may be strictly affected by the accuracy of the writing of the data signal. When a display frequency increases, it is impossible to sufficiently compensate for a threshold voltage Vth of the driving transistor, and it is difficult to write the data signal at a low grayscale level and in the case of a dark state.

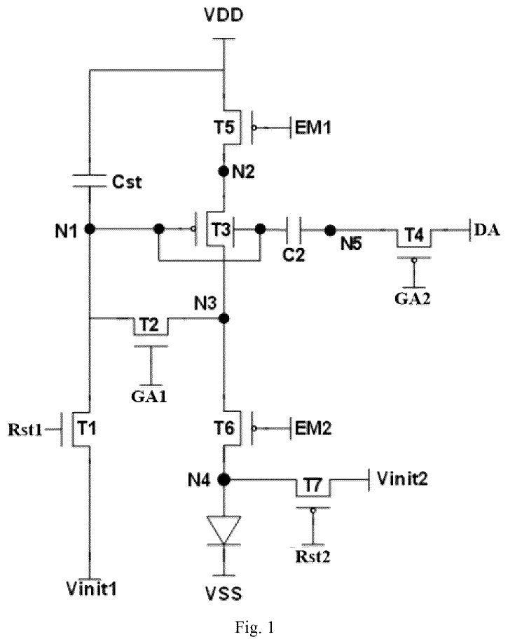

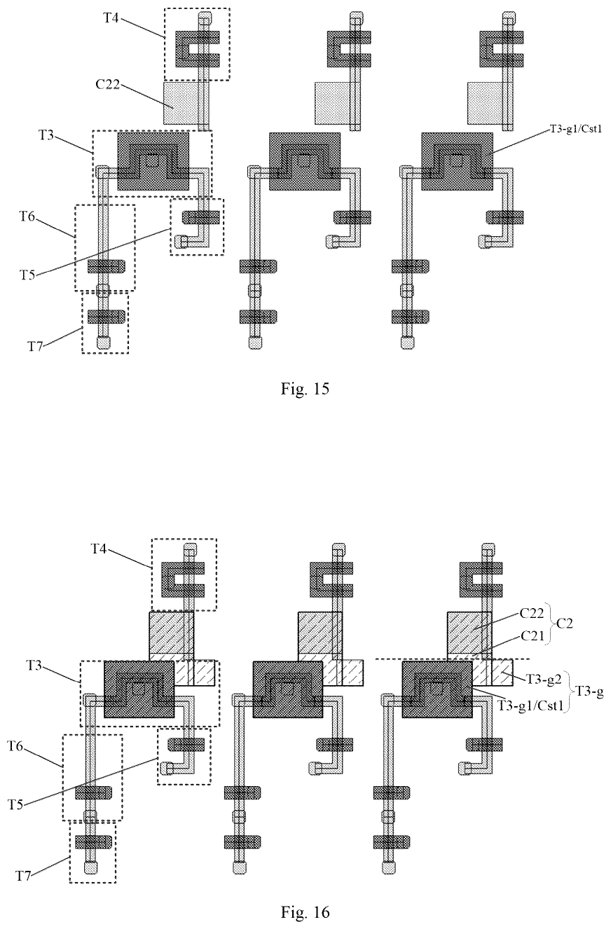

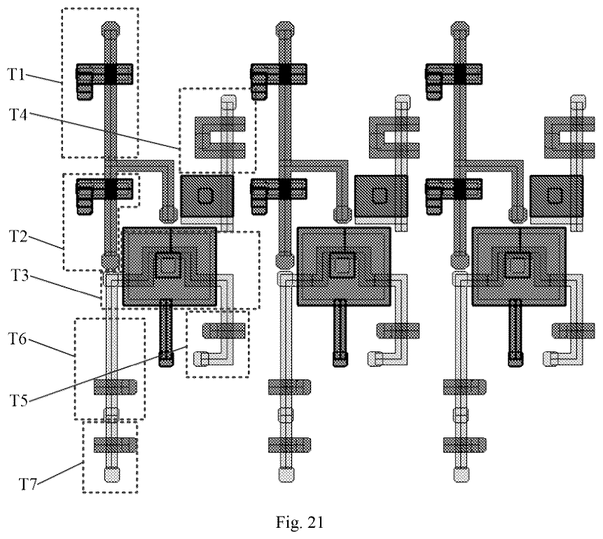

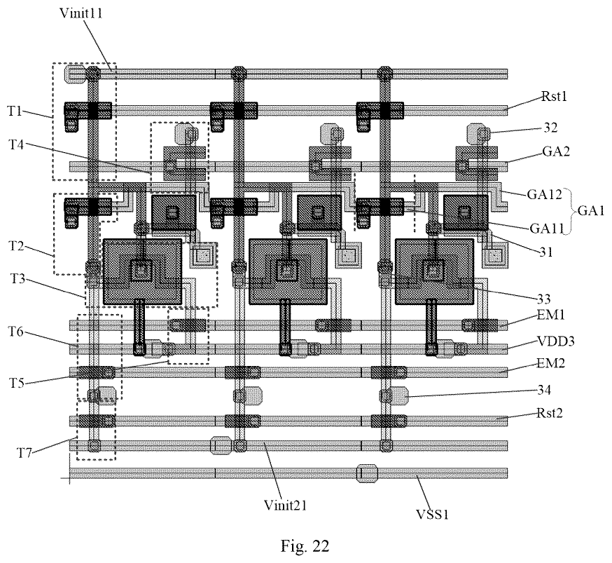

As shown in FIGS. 1, 6, 7, 9, 15, 18, and 21 to 24, the present disclosure provides in some embodiments a display substrate, which includes a base substrate, and a plurality of sub-pixels, a plurality of first scanning lines GA1, a plurality of second scanning lines GA2 and a plurality of data lines DA arranged on the base substrate. Each sub-pixel includes a sub-pixel driving circuitry, and the sub-pixel driving circuitry includes a driving transistor T3, a capacitor structure C2, a compensation transistor T2, and a data write-in transistor T4.

Gate electrodes of the compensation transistor T2 (such as T2-g1 and T2-g2) are coupled to a corresponding first scanning line GA1, a first electrode of the compensation transistor T2 is coupled to a second electrode of the driving transistor T3. and a second electrode of the compensation transistor T2 is coupled to a gate electrode T3-g of the driving transistor T3. A gate electrode T4-g of the data write-in transistor T4 is coupled to a corresponding second scanning line GA2, a first electrode of the data write-in transistor T4 is coupled to a corresponding data line DA, a second electrode of the data write-in transistor T4 is coupled to a first end of the capacitor structure C2, and a second end of the capacitor structure C2 is coupled to a gate electrode T3-g of the driving transistor T3.

Illustratively, the display substrate includes a plurality of sub-pixels, and a plurality of sub-pixel driving circuitries in the plurality of sub-pixels is arranged in an array form, i.e., arranged in rows and columns. The plurality of rows of sub-pixel driving circuitries is arranged in a second direction, and each row includes a plurality of sub-pixel driving circuitries arranged in a first direction. The plurality of columns of sub-pixel driving circuitries is arranged in the first direction, and each column includes a plurality of sub-pixel driving circuitries arranged in the second direction. Illustratively, the first direction intersects the second direction. For example, the first direction includes, but not limited to, a transverse direction, and the second direction includes, but not limited to, a longitudinal direction.

Illustratively, the sub-pixel includes a sub-pixel driving circuitry and a light-emitting element (i.e. the above-mentioned OLED element). The sub-pixel driving circuitry is coupled to an anode of the light-emitting element, and configured to apply a driving signal to the light-emitting element, so as to drive the light-emitting element to emit light.

Illustratively, the plurality of first scanning lines GA1 is arranged along the second direction, and at least a part of each first scanning line GA1 extends along the first direction. The plurality of first scanning lines GA1 corresponds to the plurality of rows of sub-pixel driving circuitries respectively, and each first scanning line GA1 is coupled to the gate electrodes of the compensation transistors T2 in a corresponding row of sub-pixel driving circuitries (such as T2-g1 and T2-g2), so as to apply a first scanning signal to the gate electrodes of each compensation transistor T2 (such as T2-g1 and T2-g2).

Illustratively, the plurality of second scanning lines GA2 is arranged along the second direction, and at least a part of each second scanning line GA2 extends along the first direction. The plurality of second scanning lines GA2 corresponds to the plurality of rows of sub-pixel driving circuitries respectively, and each second scanning line GA2 is coupled to the gate electrodes T4-g of the data write-in transistors T4 in a corresponding row of sub-pixel driving circuitries, so as to apply a second scanning signal to the gate electrodes T4-g of the data write-in transistors T4.

Illustratively, the plurality of data lines DA is arranged in the first direction, and at least a part of each data line DA extends in the second direction. The plurality of data lines DA corresponds to the plurality of columns of sub-pixel driving circuitries respectively, and each data line DA is coupled to the first electrodes of the data write-in transistors T4 in a corresponding column of sub-pixel driving circuitries, so as to apply a data signal to the first electrodes of the data write-in transistors T4.

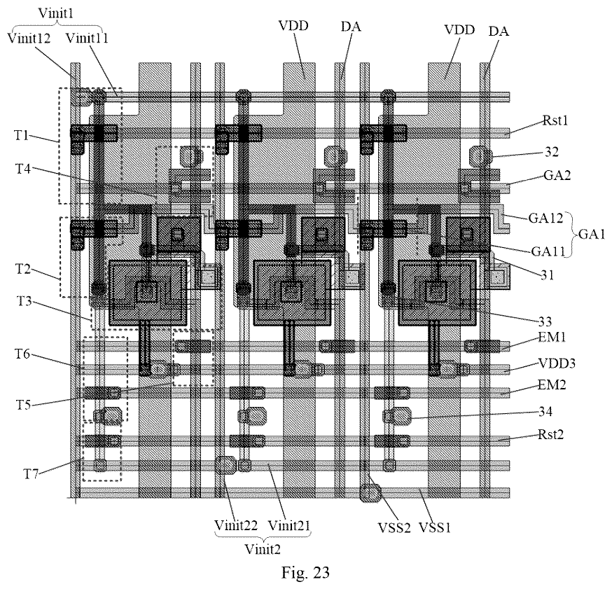

As shown in FIGS. 1 and 23, illustratively, the display substrate includes a first resetting signal line Rst1, a second resetting signal line Rst2, a first light-emission control signal line EMI, a second light-emission control signal line EM2, a first initialization signal layer Vinit1, a second initialization signal layer Vinit2, a power line VDD, and a cathode layer. The sub-pixel driving circuitry includes a driving transistor T3, a capacitor structure C2, a compensation transistor T2, a data write-in transistor T4, a first resetting transistor T1, a second resetting transistor T7, a power control transistor T5, a light-emission control transistor T6 and a storage capacitor Cst.

Gate electrodes of the first resetting transistor T1 (such as T1-g1 and T1-g2) are coupled to the corresponding first resetting signal line Rst1, a first electrode of the first resetting transistor T1 is coupled to the first initialization signal layer Vinitl, and a second electrode of the first resetting transistor T1 is coupled to a gate electrode T3-g of the driving transistor T3.

Gate electrodes of the compensation transistor T2 (such as T2-g1 and T2-g2) are coupled to the corresponding first scanning line GA1, a first electrode of the compensation transistor T2 is coupled to a second electrode of the driving transistor T3, and a second electrode of the compensation transistor T2 is coupled to the gate electrode T3-g of the driving transistor T3.

A gate electrode T4-g of the data write-in transistor T4 is coupled to the corresponding second scanning line GA2, a first electrode of the data write-in transistor T4 is coupled to the corresponding data line DA, and a second electrode of the data write-in transistor T4 is coupled to a first end of the capacitor structure C2. A second end of the capacitor structure C2 is coupled to the gate electrode T3-g of the driving transistor T3.

A gate electrode T5-g of the power control transistor T5 is coupled to the corresponding first light-emission control signal line EM1, a first electrode of the power control transistor T5 is coupled to the corresponding power line VDD, and a second electrode of the power control transistor T5 is coupled to a first electrode of the driving transistor T3.

A gate electrode T6-g of the light-emission control transistor T6 is coupled to the corresponding second light-emission control signal line EM2, a first electrode of the light-emission control transistor T6 is coupled to the second electrode of the driving transistor T3, a second electrode of the light-emission control transistor T6 is coupled to an anode of the corresponding light-emitting element, and a cathode of the light-emitting element is configured to receive a negative power signal VSS.

A gate electrode of the second resetting transistor T7 is coupled to the corresponding second resetting signal line Rst2, a first electrode of the second resetting transistor T7 is coupled to the corresponding second initialization signal layer Vinit2, and a second electrode of the second resetting transistor T7 is coupled to the anode of the corresponding light-emitting element.

A first plate Cst1 of the storage capacitor Cst is coupled to the gate electrode T3-g of the driving transistor T3, and a second plate Cst2 of the storage capacitor Cst is coupled to the corresponding power line VDD.

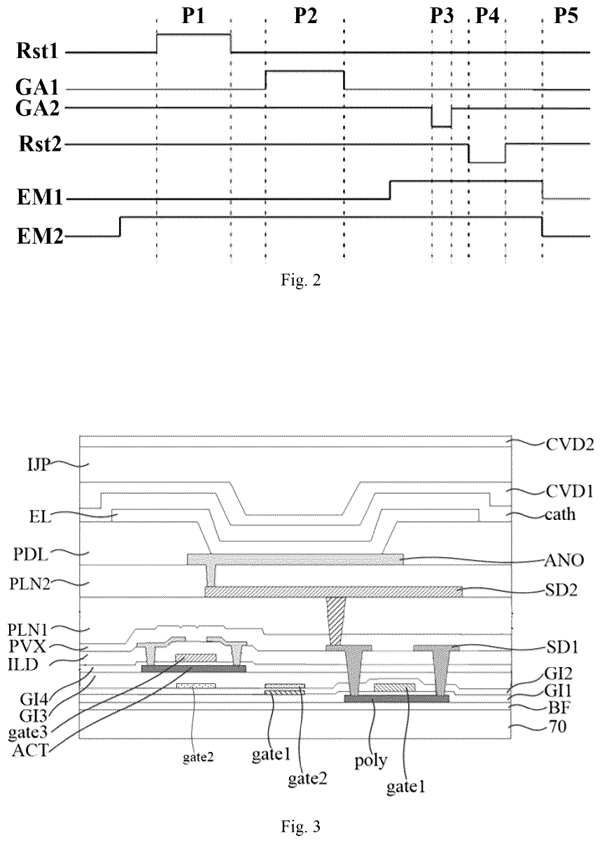

Illustratively, each of the first resetting transistor T1 and the compensation transistor T2 includes an oxide transistor. Each of the driving transistor T3, the data write-in transistor T4, the power control transistor T5, the light-emission control transistor T6 and the second resetting transistor T7 includes a low-temperature polysilicon transistor As shown in FIG. 2, a driving principle of the above-mentioned pixel driving circuitry will be described as follows.

At P1, the power control transistor T5 is maintained in an on state as within a previous frame, a first resetting signal transmitted through the first resetting signal line Rstl is at a high level, the first resetting transistor T1 is turned on, and a first initialization signal transmitted through the first initialization signal layer Vinitl is written into the gate electrode T3-g (i.e., node N1) of the driving transistor T3 so as to reset the node N1.

At P2, the power control transistor T5 is maintained in the on state as within a previous frame, the first resetting signal transmitted through the first resetting signal line Rstl is at a low level, a first scanning signal transmitted through the first scanning line GA1 is at a high level, the compensation transistor T2 is turned on, and a power signal transmitted through the power line VDD compensates for a threshold voltage Vth of the driving transistor T3. After the compensation is completed, a potential at the node N1 is Vth+Vdd, where Vdd is a voltage value of the power signal. A potential at the first electrode of the driving transistor T3, i.e. a node N2, is Vdd.

At P3, the first light-emission control signal transmitted through the first light-emission control signal line EMI is at a high level, the power control transistor T5 is turned off, the first scanning signal transmitted through the first scanning line GA1 is at a low level, the compensation transistor T2 is turned off, the second scanning signal transmitted through the second scanning line GA2 is at a low level, the data write-in transistor T4 is turned on, and the data signal transmitted through the data line DA is written into the first end of the capacitor structure C2. Due to a coupling effect of the capacitor structure C2, a potential at the node N1 becomes Vth+Vdd+Vdata, and a potential at the node N2 is maintained as Vdd, where Vdata is a voltage value of the data signal.

At P4, the second scanning signal transmitted through the second scanning line GA2 is at a high level, the data write-in transistor T4 is turned off, the second resetting signal transmitted through the second resetting signal line Rst2 is at a low level, the second resetting transistor T7 is turned on, and the second initialization signal transmitted through the second initialization signal layer Vinit2 is written into the anode (namely, node N4) of the light-emitting element to reset the node N4.

At P5, the first light-emission control signal transmitted through the first light-emission control signal line EMI and the second light-emission control signal transmitted through the second light-emission control signal line EM2 are both at a low level, the power control transistor T5 and the light-emission control transistor T6 are both turned on, the other transistors with a switching function are all turned off, and the light-emitting element emits light. In this state, Vgs=Vth+Vdd+Vdata−Vdd=Vth+Vdata.

For leakage current Id, Id=K(Vgs−Vth)²−K(Vth+Vdata−Vth)²=K(Vdata)².

Based on the above-mentioned structure of the display substrate, the gate electrodes of the compensation transistor T2 (e.g. T2-g1 and T2-g2) are coupled to a corresponding first scanning line GA1, the gate electrode T4-g of the data write-in transistor T4 is coupled to a corresponding second scanning line GA2, and the second electrode of the data write-in transistor T4 is coupled to the gate electrode T3-g of the driving transistor T3 via the capacitor structure C2, so as to independently control the compensation transistor T2 and the data write-in transistor T4, thereby to compensate for the threshold voltage of the driving transistor T3 and write the data signal within different time periods. In this way, in the case of high frequency display, it is able to sufficiently compensate for the threshold voltage of the driving transistor T3, and facilitate the writing of the data signal at a low grayscale level and in the dark state.

Furthermore, when the sub-pixel driving circuitry includes the capacitor structure C2, it is able to stabilize a voltage across the node N1 through the capacitor structure C2, thereby to prevent the potential at the node N1 from being adversely affected by the leakage current of the data write-in transistor T4.

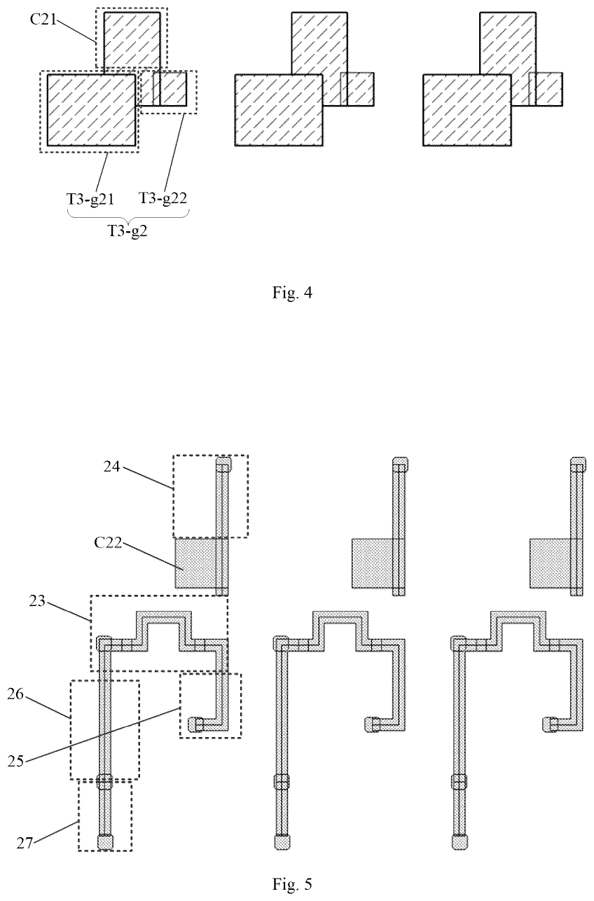

As shown in FIGS. 4 to 6, 12, 15 and 22, in some embodiments of the present disclosure, the driving transistor T3 includes a top gate electrode T3-g1, a bottom gate electrode T3-g2, and a driving active layer 23. At least a part of the bottom gate electrode T3-g2 is arranged between the top gate electrode T3-g1 and the base substrate, at least a part of the driving active layer 23 is arranged between the top gate electrode T3-g1 and the bottom gate electrode T3-g2, and the top gate electrode T3-g1 is coupled to the bottom gate electrode T3-g2 through a first conductive connection member 31.

As shown in FIG. 3, for example, the display substrate includes a buffer layer BF, a light shielding layer, a polysilicon active layer poly, a first gate insulation layer GII, a first gate metal layer gatel, a second gate insulation layer GI2, a second gate metal layer gate2, a third gate insulation layer GI3, an oxide active layer ACT, a fourth gate insulation layer GI4, a third gate metal layer gate3, an interlayer insulation layer ILD, a first source/drain metal layer SD1, and a first planarization layer PLNI, a second source/drain metal layer SD2, a second planarization layer PLN2, an anode layer ANO, a pixel definition layer PDL, a light-emitting functional layer EL, a cathode layer cath, a first inorganic encapsulation layer CVD1, an organic encapsulation layer IJP and a second inorganic encapsulation layer CVD2 laminated one on another in a direction away from the base substrate 70. The display substrate may also include a passivation layer PVX according to the practical needs. The passivation layer PVX may be arranged between the first source/drain metal layer SDI and the first planarization layer PLN1, or between the first planarization layer PLNI and the second source/drain metal layer SD2.

For example, the top gate electrode T3-g1 is arranged at a same layer, and made of a same material, as the first gate metal layer, the bottom gate electrode T3-g2 is arranged at a same layer, and made of a same material, as the light shielding layer, and the top gate electrode T3-g1 is reused as the first plate Cst1 of the storage capacitor Cst. The first conductive connection member 31 is arranged at a same layer, and made of a same material, as the first source/drain metal layer.

Illustratively, an orthogonal projection of the top gate electrode T3-g1 onto the base substrate at least partially overlaps with an orthogonal projection of the driving active layer 23 onto the base substrate. An orthogonal projection of the bottom gate electrode T3-g2 onto the base substrate at least partially overlaps with the orthogonal projection of the driving active layer 23 onto the base substrate.

Illustratively, the bottom gate electrode T3-g2 includes a body T3-g21 and a protrusion T3-g22, an orthogonal projection of the body T3-g21 onto the base substrate at least partially overlaps with the orthogonal projection of the top gate electrode T3-g1 onto the base substrate, and an orthogonal projection of the protrusion T3-g22 onto the base substrate does not overlap with the orthogonal projection of the top gate electrode T3-g1 onto the base substrate. Illustratively, the first conductive connection member 31 is coupled to the top gate electrode T3-g1 and the protrusion T3-g22.

For example, in the case that the first conductive commection member 31 is arranged at a same layer, and made of a same material, as the first source/drain metal layer, the first conductive connection member 31 is spaced apart from the bottom gate electrode T3-g2 by a large distance, so the first conductive connection member 31 is coupled to the bottom gate electrode T3-g2 through forming holes with different depths in the interlayer insulation layer. To be specific, the interlayer insulation layer includes a first interlayer insulation layer and a second interlayer insulation layer, and the first interlayer insulation layer is arranged between the base substrate and the second interlayer insulation layer. A hole is formed in the second interlayer insulation layer, and then another hole is further formed in the first interlayer insulation layer through the hole, so as to enable the first conductive connection member 31 to be coupled to the bottom gate electrode T3-g2.

When the driving transistor T3 includes both the top gate electrode T3-g1 and the bottom gate electrode T3-g2 and the top gate electrode T3-g1 is coupled to the bottom gate electrode T3-g2 through the first conductive connection member 31, it is able to write a signal to the top gate electrode T3-g1 and the bottom gate electrode T3-g2 simultaneously, thereby to rapidly write the data signal to the driving transistor T3 and rapidly compensate for the threshold voltage of the driving transistor T3.

As shown in FIGS. 4, 5, 16 and 17, in some embodiments of the present disclosure, the capacitor structure C2 includes a first plate C21 and a second plate C22, and the first plate C21 is arranged between the second plate C22 and the base substrate. The first plate C21 of the capacitor structure C2 and the bottom gate electrode T3-g2 form an integral piece, and the second plate C22 of the capacitor structure C2 and the second electrode of the data write-in transistor T4 form an integral piece.

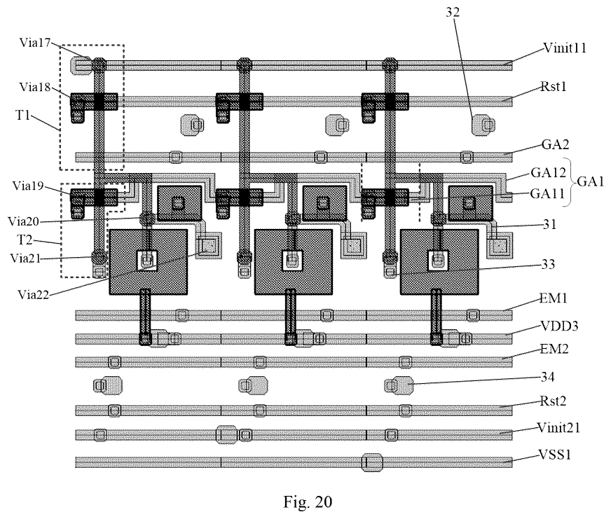

As shown in FIGS. 7 and 20, for example, the capacitor structure C2 further includes a third plate C23, the second plate C22 is arranged between the first plate C21 and the third plate C23, and the third plate C23 is coupled to the first conductive connection member 31. For example, the third plate C23 is arranged at a same layer, and made of a same material, as the second gate metal layer, and the second plate Cst2 of the storage capacitor Cst is arranged at a same layer, and made of a same material, as the second gate metal layer.

When the capacitor structure C2 includes the first plate, the second plate and the third plate C23, the capacitor structure C2 is of a sandwiched structure, so as to increase an area of an overlapping region between the plates of the capacitor structure C2, thereby to improve a capacitance of the capacitor structure C2.

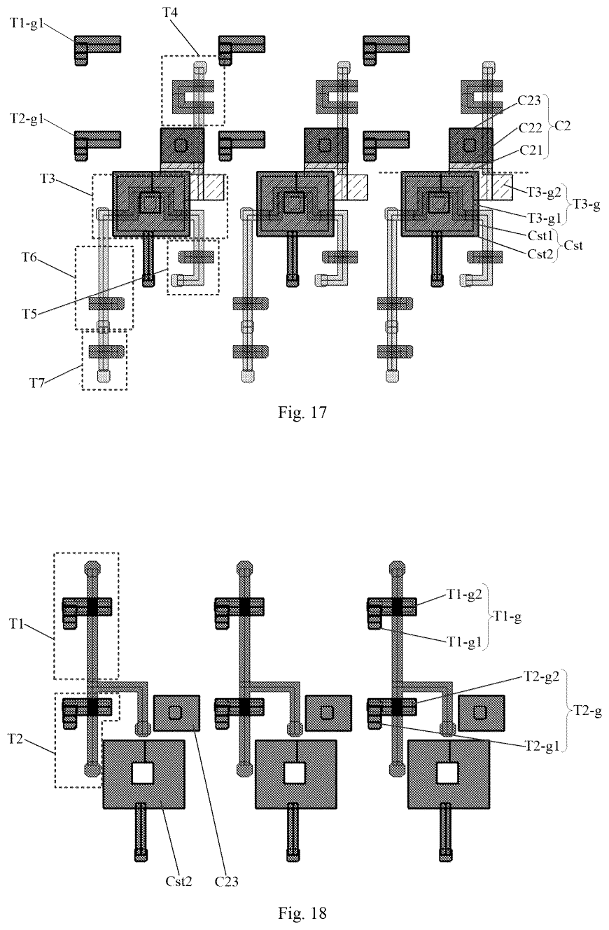

As shown in FIGS. 17 and 20, in some embodiments of the present disclosure, the first scanning line GA1 includes a plurality of first scanning members GA11 and a plurality of second scanning members GA12, the first scanning members GA11 and the second scanning members GA12 are arranged alternately along a first direction, and each first scanning member GA11 is coupled to the adjacent second scanning member GA12.

An orthogonal projection of the first scanning member GA11 onto the base substrate and the orthogonal projection of the capacitor structure C2 onto the base substrate are arranged along the first direction, and the second scanning member GA12 extends along an extension direction of a part of a boundary of the capacitor structure C2.

Illustratively, the first scanning member GAII and the second scanning member GA12 form an integral piece.

Illustratively, an orthogonal projection of the second scanning member GA12 onto the base substrate surrounds a part of the orthogonal projection of the capacitor structure C2 onto the base substrate.

Illustratively, the first scanning member GA11 is coupled to the gate electrodes of the compensation transistor T2 (e.g., T2-g1 and T2-g2).

In the embodiments of the present disclosure, when the second scanning member GA12 extends along the extension direction of a part of the boundary of the capacitor structure C2, it is able to reduce a layout space occupied by the sub-pixel driving circuitry as a whole, thereby to reduce the difficulty in the layout of the sub-pixel driving circuitry in a limited space.

As shown in FIGS. 5, 6 and 15, in some embodiments of the present disclosure, the data write-in transistor T4 includes a double-gate transistor.

Illustratively, the data write-in transistor T4 includes a data write-in active layer 24, the gate electrode T4-g of the data write-in transistor T4 is of a U-like shape, and an orthogonal projection of the gate electrode T4-g of the data write-in transistor T4 onto the base substrate overlaps with an orthogonal projection of the data write-in active layer 24 onto the base substrate at two overlapping regions.

Illustratively, at least a part of the data write-in active layer 24 extends in the second direction, and the two overlapping regions are arranged in the second direction.

At PS, a node N5 is in a floating state, and a fluctuation of a potential at the node N5 will affect the stability of the node N1 and thereby affect the display brightness. When the data write-in transistor T4 includes a double-gate transistor, it is able to prevent the current leakage at the node NS and ensure the stability of the potential at the node N5, thereby to improve the stability of the node N1 within a pixel frame and maintain the display brightness.

As shown in FIGS. 7 to 9, 17, 18, 20, and 22 to 24, in some embodiments of the present disclosure, the display substrate further includes a first initialization signal layer Vinit1 and a first resetting signal line Rst1. The sub-pixel driving circuitry further includes a first resetting transistor T1, gate electrodes of the first resetting transistor T1 (such as T1-g1 and T1-g2) are coupled to a corresponding first resetting signal line Rst1, a first electrode of the first resetting transistor T1 is coupled to the first initialization signal layer Vinit1, and a second electrode of the first resetting transistor Tl is coupled to the gate electrode T3-g of the driving transistor T3. At least one of the first resetting transistor T1 or the compensation transistor T2 includes an oxide transistor.

Illustratively, the display substrate includes a plurality of first resetting signal lines Rstl arranged in the second direction, each first resetting signal line Rst1 includes at least a part extending in the first direction. The plurality of first resetting signal lines Rstl corresponds to the plurality of rows of sub-pixel driving circuitries respectively. The first resetting signal line Rst1 is coupled to the gate electrodes of each first resetting transistor T1 (for example, T1-g1 and T1-g2) in a corresponding row of sub-pixel driving circuitries, so as to apply a first resetting signal to the first resetting transistor T1.

When at least one of the first resetting transistor T1 or the compensation transistor T2 includes an oxide transistor, it is able to reduce the risk of current leakage for the first resetting transistor T1 and/or the compensation transistor T2, thereby to improve the stability of the node N1 within the pixel frame and maintain the brightness.

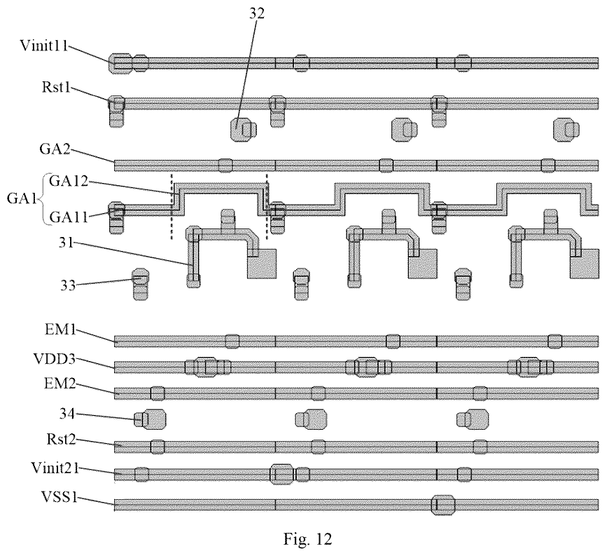

As shown in FIGS. 12, 14 and 24, in some embodiments of the present disclosure, the first initialization signal layer Vinit includes a plurality of first initialization signal lines Vinitil and a plurality of second initialization signal lines Vinit12, each first initialization signal line Vinit11 includes at least a part extending in the first direction, each second initialization signal line Vinit12 includes at least a part extending in the second direction, the first direction intersects the second direction, and the first initialization signal line Vinit11 is coupled to the second initialization signal line Vinit12.

For example, the plurality of first initialization signal lines Vinit11 is arranged along the second direction, and arranged at a same layer and made of a same material as the first source/drain metal layer. The plurality of second initialization signal lines Vinit12 is arranged along the first direction, and arranged at a same layer and made of a same material as the second source/drain metal layer.

Illustratively, each the first initialization signal line Vinit11 is coupled to the plurality of second initialization signal lines Vinit12.

Based on the above, the first initialization signal layer Vinit1 is of a grid-like structure, so as to reduce the loading of the first initialization signal layer Vinit1, and improve the uniformity of the first initialization signal transmitted through the first initialization signal layer Vinit1, thereby to improve the display quality of the display substrate.

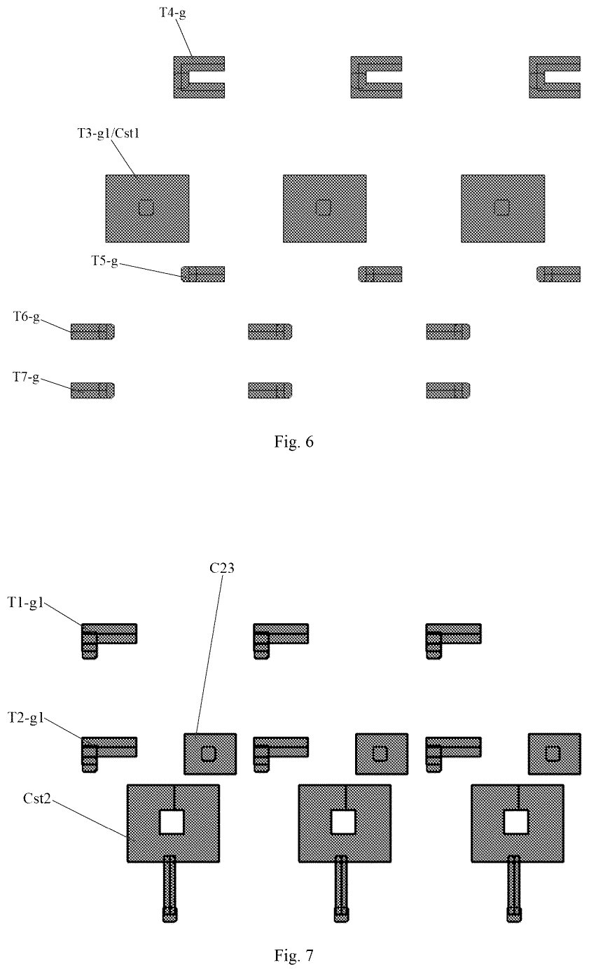

As shown in FIGS. 6, 12, 14, 15, and 22 to 24, in some embodiments of the present disclosure, the display substrate further includes a second initialization signal layer Vinit2 and a second resetting signal line Rst2. The sub-pixel driving circuitry further includes a second resetting transistor T7, a gate electrode T7-g of the second resetting transistor T7 is coupled to a corresponding second resetting signal line Rst2, a first electrode of the second resetting transistor T7 is coupled to the second initialization signal layer Vinit2, and a second electrode of the second resetting transistor T7 is coupled to the anode of the light-emitting element in the sub-pixel. The second initialization signal layer Vinit2 includes a plurality of third initialization signal lines Vinit21 and a plurality of fourth initialization signal lines Vinit22, each third initialization signal line Vinit21 includes at least a part extending in the first direction, each fourth initialization signal line Vinit22 includes at least a part extending in the second direction, and the third initialization signal line Vinit21 is coupled to the fourth initialization signal line Vinit22.

Illustratively, the display substrate includes a plurality of second resetting signal lines Rst2 arranged in the second direction, and each second resetting signal line Rst2 includes at least a part extending in the first direction. The plurality of second resetting signal lines Rst2 corresponds to the plurality of rows of sub-pixel driving circuitries respectively. The second resetting signal line Rst2 is coupled to the gate electrode T7-g of each second resetting transistor T7 in a corresponding row of sub-pixel driving circuitries, and configured to apply a second resetting signal to the second resetting transistor T7.

Illustratively, the plurality of third initialization signal lines Vinit21 is arranged along the second direction, and arranged at a same layer and made of a same material as the first source/drain metal layer. The plurality of fourth initialization signal lines Vinit22 is arranged along the first direction, and arranged at a same layer and made of a same material as the second source/drain metal layer.

Illustratively, each third initialization signal line Vinit21 is coupled to the plurality of fourth initialization signal lines Vinit22.

Based on the above, the second initialization signal layer Vinit2 is of a grid-like structure, so as to reduce the loading of the second initialization signal layer Vinit2, and improve the uniformity of the second initialization signal transmitted through the second initialization signal layer Vinit2, thereby to improve the display quality of the display substrate.

In some embodiments of the present disclosure, the display substrate further includes a cathode layer and at least one cathode compensation layer, at least a part of the cathode compensation layer is arranged between the cathode layer and the base substrate, and the cathode compensation layer includes a plurality of cathode compensation lines coupled to the cathode layer.

As shown in FIGS. 12, 14 and 24, for example, the display substrate includes a first cathode compensation layer and a second cathode compensation layer, and at least a part of the first cathode compensation layer is arranged between the second cathode compensation layer and the base substrate. The first cathode compensation layer includes a plurality of first cathode compensation lines VSS1, and each first cathode compensation line VSS1 includes at least a part extending in the first direction. The second cathode compensation layer includes a plurality of second cathode compensation lines VSS2, and each second cathode compensation line VSS2 includes at least a part extending in the second direction. The first cathode compensation line VSS1 is coupled to the second cathode compensation line VSS2.

Illustratively, the first cathode compensation layer is arranged at a same layer, and made of a same material, as the first source/drain metal layer. The second cathode compensation layer is arranged at a same layer, and made of a same material, as the second source/drain metal layer.

Illustratively, the first cathode compensation layer includes a plurality of first cathode compensation lines VSS1 arranged in the second direction, and the second cathode compensation layer includes a plurality of second cathode compensation lines VSS2 arranged in the first direction.

Illustratively, each first cathode compensation line VSS1 is coupled to the plurality of second cathode compensation lines VSS2.

Illustratively, the display substrate includes a display region and a peripheral region surrounding the display region. The cathode compensation layer is, but not limited to, coupled to the cathode layer at the peripheral region.

Based on the above, when the display substrate includes the first cathode compensation layer and the second cathode compensation layer, the cathode compensation layer is of a grid-like shape, so as to reduce the loading of the cathode layer, thereby to reduce a voltage across the display substrate.

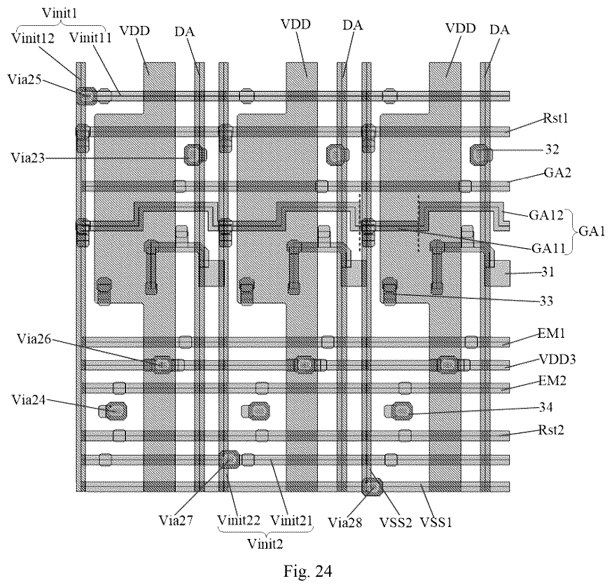

As shown in FIG. 24, in some embodiments of the present disclosure, the second initialization signal lines Vinit12, the fourth initialization signal lines Vinit22 and the second cathode compensation lines VSS2 are arranged alternately in the first direction.

Illustratively, in a layout region of three adjacent columns of sub-pixel driving circuitries in the first direction, the second initialization signal line Vinit12 is arranged in a layout region of a first column of sub-pixel driving circuitries, the fourth initialization signal line Vinit22 is arranged in a layout region of a second column of sub-pixel driving circuitries, and the second cathode compensation line VSS2 is arranged in a layout region of a third column of sub-pixel driving circuitries.

Illustratively, three adjacent columns of sub-pixel driving circuitries are taken as one repeating unit, and the display substrate includes a plurality of repeating units arranged along the first direction.

Based on the above, it is able to reduce the difficulty in the layout of the display substrate while improving the display effect of the display substrate.

As shown in FIGS. 7, 8, 9, 14, 18 and 23, in some embodiments of the present disclosure, the first resetting transistor T1 includes a first resetting active layer 21, and the compensation transistor T2 includes a compensation active layer 22.

The display substrate further includes a plurality of power lines VDD, and each power line VDD includes at least a part extending in the second direction. An orthogonal projection of the power line VDD onto the base substrate at least partially overlaps with an orthogonal projection of the first resetting active layer 21 onto the base substrate, and/or the orthogonal projection of the power line VDD onto the base substrate at least partially overlaps with the orthogonal projection of the compensation active layer 22 onto the base substrate.

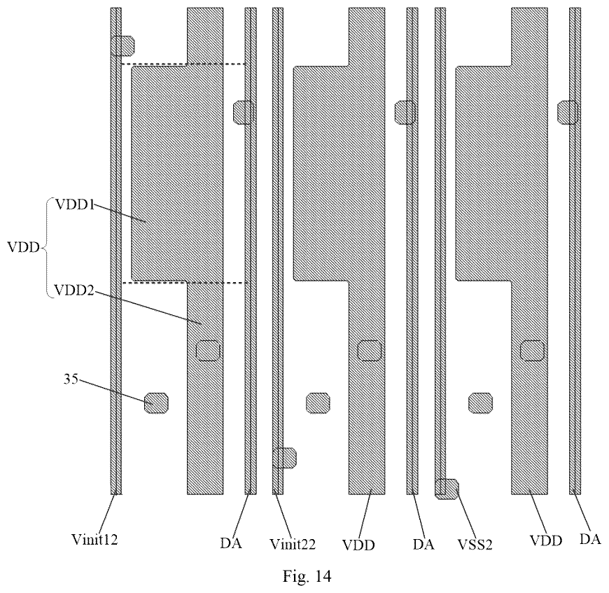

As shown in FIG. 14, for example, the power line VDD includes a plurality of first power members VDD1 and a plurality of second power members VDD2, the first power members VDD1 and the second power members VDD2 are arranged alternately in the second direction, each first power member VDD1 is coupled to the adjacent second power member VDD2, and a width of the first power member VDD1 in the first direction is greater than a width of the second power member VDD2 in the first direction. An orthogonal projection of the first power member VDD1 onto the base substrate at least partially overlaps with the orthogonal projection of the first resetting active layer 21 onto the base substrate, and/or the orthogonal projection of the first power member VDD1 onto the base substrate at least partially overlaps with the orthogonal projection of the compensation active layer 22 onto the base substrate.

Illustratively, the first resetting active layer 21 includes a first resetting channel member, and an orthogonal projection of the first resetting channel member onto the base substrate overlaps with the orthogonal projections of the gate electrodes of the first resetting transistor T1 (e.g., T1-g1 and T1-g2) onto the base substrate. The compensation active layer 22 includes a compensation channel member, and an orthogonal projection of the compensation channel member onto the base substrate overlaps with the orthogonal projections of the gate electrodes of the compensation transistor T2 (e.g., T2-g1 and T2-g2) onto the base substrate. The orthogonal projection of the first power member VDD1 onto the base substrate covers the orthogonal projection of the first resetting channel member onto the base substrate, and/or the orthogonal projection of the first power member VDD1 onto the base substrate covers the orthogonal projection of the compensation channel member onto the base substrate.

Each of the first resetting transistor T1 and the compensation transistor T2 includes an oxide transistor. Based on the above, the power line VDD shields a channel of the oxide transistor, so as to improve the stability of the first resetting transistor T1 and the compensation transistor T2.

As shown in FIGS. 12, 14 and 22 to 24, in some embodiments of the present disclosure, the display substrate further includes a plurality of power compensation lines VDD3, each power compensation line VDD3 includes at least a part extending in the first direction, the first direction intersects the second direction, and the power compensation line VDD3 is coupled to the power line VDD.

Illustratively, the display substrate includes a plurality of power compensation lines VDD3 arranged in the second direction, and the power compensation line VDD3 is arranged at a same layer, and made of a material, as the first source/drain metal layer.

Illustratively, the power compensation line VDD3 is coupled to the plurality of power lines VDD.

Based on the above, the power lines VDD and the power compensation lines VDD3 together form a grid-like structure, so as to reduce the overall loading of the film layers for transmitting a power signal, thereby to improve the display uniformity of the display substrate.

As shown in FIG. 14, in some embodiments of the present disclosure, the data line DA is arranged between the power line VDD and the second initialization signal line Vinit12; and/or the data line DA is arranged between the power line VDD and the fourth initialization signal line Vinit22; and/or the data line DA is arranged between the power line VDD and the second cathode compensation line VSS2.

Based on the above, it is able to prevent the occurrence of any interference caused by a signal on the data signal transmitted through the data line DA. thereby to improve the stability of the data signal transmitted through the data line DA.

As shown in FIGS. 12, 14, 15 and 23, in some embodiments of the present disclosure, the display substrate further includes a plurality of first light-emission control signal lines EM1 and a plurality of second light-emission control signal lines EM2, and the sub-pixel driving circuitry further includes a power control transistor T5 and a light-emission control transistor T6.

A gate electrode T5-g of the power control transistor T5 is coupled to a corresponding first light-emission control signal line EM1, a first electrode of the power control transistor T5 is coupled to a corresponding power line VDD, and a second electrode of the power control transistor T5 is coupled to the first electrode of the driving transistor T3.

A gate electrode T6-g of the light-emission control transistor T6 is coupled to a corresponding second light-emission control signal line EM2, a first electrode of the light-emission control transistor T6 is coupled to the second electrode of the driving transistor T3, and a second electrode of the light-emission control transistor T6 is coupled to the anode of the light-emitting element in the sub-pixel.

Illustratively, the plurality of power lines VDD extends in the first direction, and corresponds to the plurality of columns of sub-pixel driving circuitries respectively. Each power line VDD is coupled to the first electrodes of the power control transistors T5 in a corresponding column of sub-pixel driving circuitries.

Illustratively, the plurality of first light-emission control signal lines EM1 is arranged along the second direction and corresponds to the plurality of rows of sub-pixel driving circuitries respectively. Each first light-emission control signal line EM1 is coupled to the gate electrodes T5-g of the power control transistors T5 in a corresponding row of sub-pixel driving circuitries.

Illustratively, the plurality of second light-emission control signal lines EM2 is arranged along the second direction and corresponds to the plurality of rows of sub-pixel driving circuitries respectively. Each second light-emission control signal line EM2 is coupled to the gate electrodes T6-g of the light-emission control transistors T6 in a corresponding row of sub-pixel driving circuitries.

Based on the above, it is able to control the power control transistor TS and the light-emission control transistor T6 independent of each other.

As shown in FIG. 12, in some embodiments of the present disclosure, in a layout region of the same sub-pixel driving circuitry, the first initialization signal line Vinit11, the first resetting signal line Rst1, the second scanning line GA2, the first scanning line GA1, the first light-emission control signal line EM1, the power compensation line VDD3, the second light-emission control signal line EM2, the second resetting signal line Rst2, the third initialization signal line Vinit21 and the first cathode compensation line VSS1 are arranged in sequence along the second direction.

For example, the display substrate includes a first source/drain metal layer and a second source/drain metal layer. The first initialization signal line Vinit11, the first resetting signal line Rst1, the second scanning line GA2, the first scanning line GA1, the first light-emission control signal line EM1, the power compensation line VDD3, the second light-emission control signal line EM2, the second resetting signal line Rst2, the third initialization signal line Vinit21 and the first cathode compensation line VSS1 are all arranged at a same layer, and made of a same material, as the first source/drain metal layer. The power line VDD, the data line DA, the second initialization signal line Vinit12, the fourth initialization signal line Vinit22, and the second cathode compensation line VSS2 are all arranged at a same layer, and made of a same material, as the second source/drain metal layer.

Based on the above, it is able to reduce the loading of each signal line, thereby to improve a charging rate.

FIG. 5 shows the driving active layer 23, the data write-in active layer 24, a power control active layer 25, a light-emission control active layer 26, and a second resetting active layer 27.

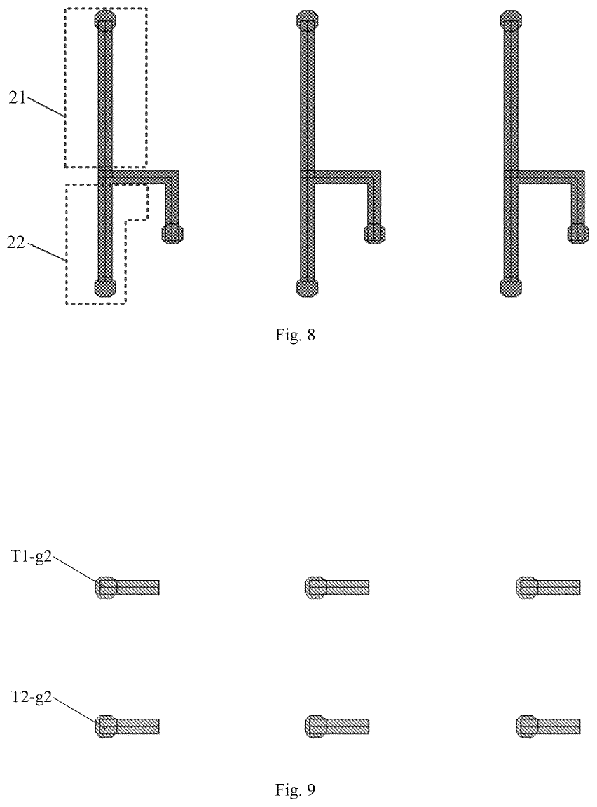

FIG. 8 shows the first resetting active layer 21 and the compensation active layer 22.

FIGS. 12 and 14 show the first conductive connection member 31, a second conductive connection member 32, a third conductive connection member 33, a fourth conductive connection member 34, and a fifth conductive connection member 35.

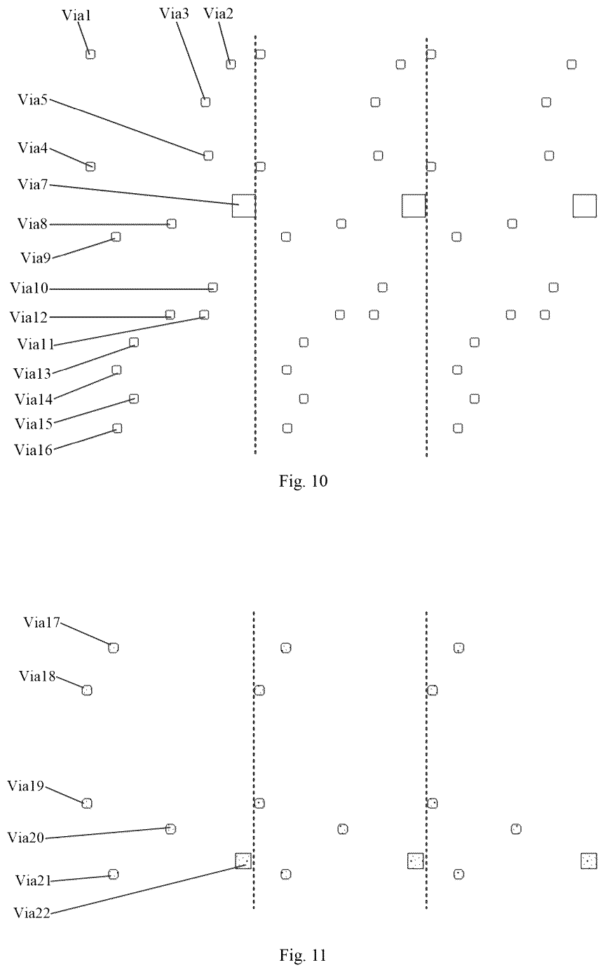

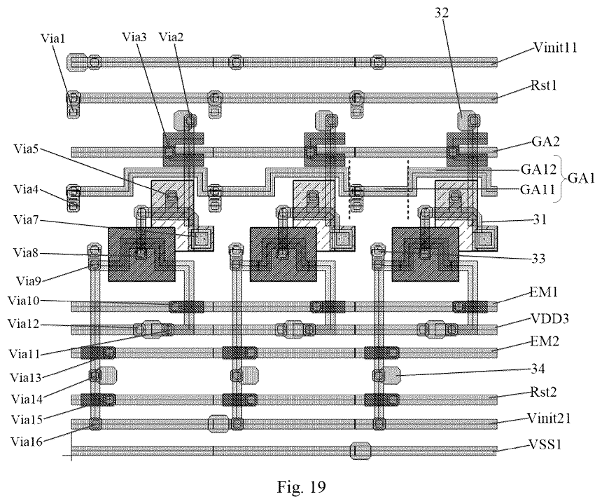

As shown in FIGS. 10, 11, 12, 19 and 20, the first conductive connection member 31 is coupled to the top gate electrode T3-g1 through an eighth via hole Via8, coupled to the second electrode of the first resetting transistor T1 and the second electrode of the compensation transistor T2 through a via hole Via20, coupled to the third plate C23 of the capacitor structure C2 through a fifth via hole Vias, and coupled to the bottom gate electrode T3-g2 through a via hole Via22 and a via hole Via7.

The second conductive connection member 32 is coupled to the first electrode of the data write-in transistor T4 through a second via hole Via2, and coupled to a corresponding data line DA through a via hole Via23.

The third conductive connection member 33 is coupled to the second electrode of the driving transistor T3 through a ninth via hole Via9, and coupled to the first electrode of the compensation transistor T2 through a twenty-first via hole Via21.

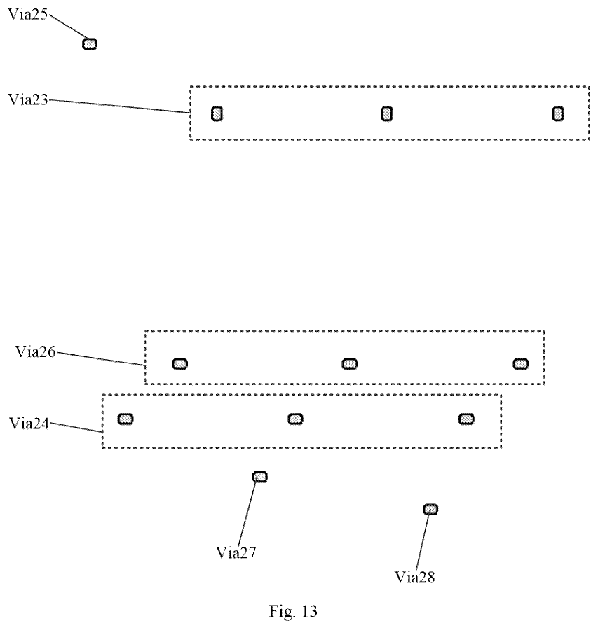

As shown in FIGS. 13, 19, 23 and 24, the fourth conductive connection member 34 is coupled to the second electrode of the light-emission control transistor T6 through a fourteenth via hole Via14, and coupled to the fifth conductive connection member 35 through a twenty-fourth via hole Via24.

As shown in FIGS. 13 and 24, the first initialization signal line Vinitil is coupled to the second initialization signal line Vinit12 through a twenty-fifth via hole Via25, and coupled to the first electrode of the first resetting transistor T1 through a seventeenth via hole Via17.

As shown in FIGS. 10, 11, 12, 19 and 20, the first resetting signal line Rst1 is coupled to the gate electrode T1-g2 of the first resetting transistor T1 through an eighteenth via hole Via18, and coupled to the gate electrode T1-g1 of the first resetting transistor T1 through a first via hole Vial. It should be appreciated that, the first resetting transistor T1 includes an oxide transistor including a gate electrode T1-g1 made of the second gate metal layer and a gate electrode T1-g2 made of the third gate metal layer.

As shown in FIGS. 10, 12, 19 and 20, the second scanning line GA2 is coupled to the gate electrode T4-g of the data write-in transistor T4 through a third via hole Via3.

As shown in FIGS. 10, 11, 12, 19 and 20, the first scanning line GAL is coupled to the gate electrode T2-g2 of the compensation transistor T2 through a nineteenth via hole Via19, and coupled to the gate electrode T2-g1 of the compensation transistor T2 through a fourth via hole Via4. It should be appreciated that, the compensation transistor T2 includes an oxide transistor including a gate electrode T2-g1 made of the second gate metal layer and a gate electrode T2-g2 made of the third gate metal layer.

As shown in FIGS. 10, 12, 19 and 20, the first light-emission control signal line EM1 is coupled to the gate electrode T5-g of the power control transistor T5 through a tenth via hole Via10.

As shown in FIGS. 10, 11, 12, 13, 19, and 20 to 24, the power compensation line VDD3 is coupled to the first electrode of the power control transistor T5 through an eleventh via hole Viall, coupled to the second plate Cst2 of the storage capacitor Cst through a twelfth via hole Via12, and coupled to the power line VDD through a twenty-sixth via hole Via26. The second light-emission control signal line EM2 is coupled to the gate electrode T6-g of the light-emission control transistor T6 through a thirteenth via hole Via13. The second resetting signal line Rst2 is coupled to the gate electrode T7-g of the second resetting transistor T7 through a fifteenth via hole Via15. The third initialization signal line Vinit21 is coupled to the first electrode of the second resetting transistor T7 through a sixteenth via hole Vial6. The third initialization signal line Vinit21 is coupled to the fourth initialization signal line Vinit22 through a twenty-seventh via hole Via27. The first cathode compensation line VSS1 is coupled to the second cathode compensation line VSS2 through a twenty-eighth via hole Via28.

The present disclosure further provides in some embodiments a display device which includes the above-mentioned display substrate.

It should be appreciated that, the display device may be any product or member having a display function, such as television, display, digital photo frame, mobile phone or tablet computer. The display device may further include a flexible circuit board, a printed circuit board and a back plate.

According to the display substrate in the embodiments of the present disclosure, the gate electrodes of the compensation transistor are coupled to a corresponding first scanning line, the gate electrode of the data write-in transistor is coupled to a corresponding second scanning line, and the second electrode of the data write-in transistor is coupled to the gate electrode of the driving transistor via the capacitor structure, so as to independently control the compensation transistor and the data write-in transistor, thereby to compensate for the threshold voltage of the driving transistor and write the data signal within different time periods. In this way, in the case of high frequency display, it is able to sufficiently compensate for the threshold voltage of the driving transistor, and facilitate the writing of the data signal at a low grayscale level and in the dark state. When the display device includes the above-mentioned display substrate, it also has the above-mentioned beneficial effects, which will not be particularly defined herein.

It should be appreciated that, when a signal line extends along a direction X, it means that a primary portion of the signal line, e.g., a line, a segment or a strip-like body, extends along the direction X, and an extension length of the primary portion is greater than an extension length of a secondary portion of the signal line, which is coupled to the primary portion, in the other direction.

It should be further appreciated that, the layout region occupied by the sub-pixel driving circuitry may be a region where the sub-pixel driving circuitry is located. Illustratively, the region is, but not limited to, of a rectangular shape.

It should be further appreciated that, the expression “at a same layer” refers to that the film layers are arranged on a same structural layer. Alternatively, for example, the film layers on a same layer may be layer structures formed through forming thin layers for forming specific patterns through a single-film-forming process and then patterning the film layers with a same mask through a single patterning process. Depending on different specific patterns, a single patterning process may include multiple exposing, development or etching processes, and the specific patterns in the layer structure may be continuous or discontinuous. These specific patterns may also be arranged at different levels or have different thicknesses.

In the embodiments of the present disclosure, the order of the steps is not limited to the serial numbers thereof. For a person skilled in the art, any change in the order of the steps shall also fall within the scope of the present disclosure if without any creative effort.

It should be further appreciated that, the above embodiments have been described in a progressive manner, and the same or similar contents in the embodiments have not been repeated, i.e., each embodiment has merely focused on the difference from the others. Especially, the method embodiments are substantially similar to the product embodiments, and thus have been described in a simple manner.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “include” or “including” intends to indicate that an element or object before the word contains an element or object or equivalents thereof listed after the word, without excluding any other element or object. Such words as “connect/connected to” or “couple/coupled to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

It should be appreciated that, in the case that such an element as layer, film, region or substrate is arranged “on” or “under” another element, it may be directly arranged “on” or “under” the other element, or an intermediate element may be arranged therebetween.

In the above description, the features, structures, materials or characteristics may be combined in any embodiment or embodiments in an appropriate manner.

The above embodiments are for illustrative purposes only, but the present disclosure is not limited thereto. Obviously, a person skilled in the art may make further modifications and improvements without departing from the spirit of the present disclosure, and these modifications and improvements shall also fall within the scope of the present disclosure.

1. A display substrate, comprising a base substrate, and a plurality of sub-pixels, a plurality of first scanning lines, a plurality of second scanning lines and a plurality of data lines arranged on the base substrate, wherein each sub-pixel comprises a sub-pixel driving circuitry, and the sub-pixel driving circuitry comprises a driving transistor, a capacitor structure, a compensation transistor and a data write-in transistor;
a gate electrode of the compensation transistor is coupled to a corresponding first scanning line, a first electrode of the compensation transistor is coupled to a second electrode of the driving transistor, and a second electrode of the compensation transistor is coupled to a gate electrode of the driving transistor; and
a gate electrode of the data write-in transistor is coupled to a corresponding second scanning line, a first electrode of the data write-in transistor is coupled to a corresponding data line, a second electrode of the data write-in transistor is coupled to a first end of the capacitor structure, and a second end of the capacitor structure is coupled to the gate electrode of the driving transistor.

2. The display substrate according to claim I, wherein the driving transistor comprises a top gate electrode, a bottom gate electrode and a driving active layer, at least a part of the bottom gate electrode is arranged between the top gate electrode and the base substrate, at least a part of the driving active layer is arranged between the top gate electrode and the bottom gate electrode, and the top gate electrode is coupled to the bottom gate electrode through a first conductive connection member.

3. The display substrate according to claim 2, wherein the capacitor structure comprises a first plate and a second plate, the first plate is arranged between the second plate and the base substrate, the first plate is coupled to the bottom gate electrode to form an integral piece, and the second plate is coupled to the second electrode of the data write-in transistor to form an integral piece.

4. The display substrate according to claim 3, wherein the capacitor structure further comprises a third plate, the second plate is arranged between the first plate and the third plate, and the third plate is coupled to the first conductive connection member.

5. The display substrate according to claim 1, wherein the first scanning line comprises a plurality of first scanning members and a plurality of second scanning members, the first scanning members and the second scanning members are arranged alternately along a first direction, and each first scanning member is coupled to the adjacent second scanning member; and
an orthogonal projection of the first scanning member onto the base substrate and an orthogonal projection of the capacitor structure onto the base substrate are arranged along the first direction, and the second scanning member extends along an extension direction of a part of a boundary of the capacitor structure.

6. The display substrate of claim 1, wherein the data write-in transistor comprises a double-gate transistor.

7. The display substrate according to claim 6, wherein the data write-in transistor comprises a data write-in active layer, the gate electrode of the data write-in transistor has a U-shaped structure, and an orthogonal projection of the gate electrode of the data write-in transistor onto the base substrate overlaps with an orthogonal projection of the data write-in active layer onto the base substrate at two overlapping regions.

8. The display substrate according to claim 1, further comprising a first initialization signal layer and first resetting signal lines, wherein the sub-pixel driving circuitry further comprises a first resetting transistor, a gate electrode of the first resetting transistor is coupled to a corresponding first resetting signal line, a first electrode of the first resetting transistor is coupled to the first initialization signal layer, a second electrode of the first resetting transistor is coupled to the gate electrode of the driving transistor, and at least one of the first resetting transistor or the compensation transistor comprises an oxide transistor.

9. The display substrate according to claim 8, wherein the first initialization signal layer comprises a plurality of first initialization signal lines and a plurality of second initialization signal lines, each first initialization signal line comprises at least a part extending in a first direction, each second initialization signal line comprises at least a part extending in a second direction, the first direction intersects the second direction, and the first initialization signal line is coupled to the second initialization signal line.

10. The display substrate according to claim 9, further comprising a second initialization signal layer and second resetting signal lines, wherein the sub-pixel driving circuitry further comprises a second resetting transistor, a gate electrode of the second resetting transistor is coupled to a corresponding second resetting signal line, a first electrode of the second resetting transistor is coupled to the second initialization signal layer, and a second electrode of the second resetting transistor is coupled to an anode of a light-emitting element in the sub-pixel; and
the second initialization signal layer comprises a plurality of third initialization signal lines and a plurality of fourth initialization signal lines, each third initialization signal line comprises at least a part extending in the first direction, each fourth initialization signal line comprises at least a part extending in the second direction, and the third initialization signal line is coupled to the fourth initialization signal line.

11. The display substrate according to claim 10, further comprising a cathode layer and at least one cathode compensation layer, wherein at least a part of the cathode compensation layer is arranged between the cathode layer and the base substrate, and the cathode compensation layer comprises a plurality of cathode compensation lines coupled to the cathode layer.

12. The display substrate according to claim 11, further comprising a first cathode compensation layer and a second cathode compensation layer, wherein at least a part of the first cathode compensation layer is arranged between the second cathode compensation layer and the base substrate, the first cathode compensation layer comprises a plurality of first cathode compensation lines, each first cathode compensation line comprises at least a part extending in the first direction, the second cathode compensation layer comprises a plurality of second cathode compensation lines, each second cathode compensation line comprises at least a part extending in the second direction, and the first cathode compensation line is coupled to the second cathode compensation line.

13. The display substrate according to claim 12, wherein the second initialization signal lines, the fourth initialization signal lines, and the second cathode compensation lines are arranged alternately in the first direction.

14. The display substrate according to claim 12, wherein the first resetting transistor comprises a first resetting active layer, and the compensation transistor comprises a compensation active layer, wherein the display substrate further comprises a plurality of power lines, each power line comprises at least a part extending in the second direction, an orthogonal projection of the power line onto the base substrate at least partially overlaps with an orthogonal projection of the first resetting active layer onto the base substrate, and/or the orthogonal projection of the power line onto the base substrate at least partially overlaps with an orthogonal projection of the compensation active layer onto the base substrate.

15. The display substrate according to claim 14, further comprising a plurality of power compensation lines, wherein each power compensation line comprises at least a part extending in the first direction, the first direction intersects the second direction, and the power compensation line is coupled to the power line.

16. The display substrate according to claim 14, wherein the data line is arranged between the power line and the second initialization signal line; and/or the data line is arranged between the power line and the fourth initialization signal line;
and/or the data line is arranged between the power line and the second cathode compensation line.

17. The display substrate according to claim 14, further comprising a plurality of first light-emission control signal lines and a plurality of second light-emission control signal lines, wherein the sub-pixel driving circuitry further comprises a power control transistor and a light-emission control transistor;
a gate electrode of the power control transistor is coupled to a corresponding first light-emission control signal line, a first electrode of the power control transistor is coupled to a corresponding power line, and a second electrode of the power control transistor is coupled to a first electrode of the driving transistor; and
a gate electrode of the light-emission control transistor is coupled to a corresponding second light-emission control signal line, a first electrode of the light-emission control transistor is coupled to the second electrode of the driving transistor, and a second electrode of the light-emission control transistor is coupled to the anode of the light-emitting element in the sub-pixel.

18. The display substrate according to claim 17, wherein the first initialization signal line, the first resetting signal line, the second scanning line, the first scanning line, the first light-emission control signal line, the power compensation line, the second light-emission control signal line, the second resetting signal line, the third initialization signal line and the first cathode compensation line are sequentially arranged in the second direction in a layout region of a same sub-pixel driving circuitry.

19. The display substrate according to claim 18, further comprising a first source/drain metal layer, wherein the first initialization signal line, the first resetting signal line, the second scanning line, the first scanning line, the first light-emission control signal line, the power compensation line, the second light-emission control signal line, the second resetting signal line, the third initialization signal line and the first cathode compensation line are arranged at a same layer and made of a same material as the first source/drain metal layer.

20. A display device, comprising the display substrate according to claim 1.
